(19) United States
(12) Patent Application Publication
(10) Pub. No.: US 2013/0092228 A1
(43) Pub. Date: Apr. 18, 2013

(54) MULTILAYER FILM WITH OXYGEN PERMEATION BARRIER FOR THE PRODUCTION OF PHOTOVOLTAIC MODULES

(71) Applicants: Andreas PAWLIK, Recklinghausen (DE); Martin WIELPUETZ, Senden (DE); Harald HAEGER, Luedinghausen (DE)

(72) Inventors: Andreas PAWLIK, Recklinghausen (DE); Martin WIELPUETZ, Senden (DE); Harald HAEGER, Luedinghausen (DE)

(21) Appl. No.: 13/649,562

(22) Filed: Oct. 11, 2012

(30) Foreign Application Priority Data
Oct. 14, 2011 (DE) 10 2011 084 523.2

(51) Int. Cl. B32B 27/08; B32B 27/34; B32B 27/28; H01L 31/0203

(52) U.S. Cl. 136/256; 428/500; 428/339; 428/213

(57) ABSTRACT

A multilayered film and a photovoltaic module where the oxidation-sensitive solar cell is protected against ingress of oxygen provided. The solar cell is protected by the multilayer film as a back cover. The multilayer film comprises the following layers in direct succession: a solar cell-facing layer of a moulding composition comprising at least 70% by weight of EVOH, an adhesion promoter layer, a middle layer of a thermoplastic moulding composition, an optional adhesion promoter layer, and an outer layer comprising at least 35% by weight of polyamide.

### CROSS REFERENCE TO RELATED APPLICATIONS

This application claims priority to DE 102011084523.2 filed Oct. 14, 2011, the disclosure of which is incorporated herein by reference in its entirety.

### BACKGROUND OF THE INVENTION

The invention relates to film systems with a barrier layer against oxygen made of EVOH suitable for the production of solar modules.

Solar modules, frequently also referred to as photovoltaic modules, serve for electrical power generation from sunlight and consist of a laminate which comprises a solar cell system as the core layer. This core layer is encased with encapsulation materials which serve as protection against mechanical and weathering-related influences.

In conventional solar modules, the active solar cell is positioned between a front cover and a back cover. The front cover is transparent, generally consists of glass; and is bonded by means of an adhesion promoter layer which often contains an ethylene-vinyl acetate copolymer to the layer comprising the solar cell. The back cover provides electric shielding, serves as protection against weathering influences such as UV light and acts as a moisture barrier.

Film composites composed of fluoropolymer films and polyester may conventionally be employed as a back cover. The fluoropolymer film on the outside provides weathering resistance, while the polyester film is utilized to obtain mechanical stability and electrical insulation properties. A further fluoropolymer film on the inside serves for attachment to the sealing layer of the solar cell system. However, such fluoropolymer films have only low adhesion to the sealing layer which is used as embedding material for the solar cells themselves. In addition, the fluoropolymer film contributes to electrical insulation only to a minor degree, which results in the need to use a comparatively thick polyester film.

WO 2008138022 therefore proposes replacing the two fluoropolymer films in such composites with films of nylon-12 (PA12). In a development thereof, WO 2011066595 proposes that the solar cell-facing thermoplastic layer comprise a light-reflecting filler such as titanium dioxide, while the solar cell-remote thermoplastic layer comprise a second filler such as glass fibres, wollastonite or mica, which brings about a higher thermal conductivity of this layer. Illustrative thermoplastics come from the group of the polyamides, polyesters or blends of polyamide and polyolefin. Explicit mention is made of PA11, PA12 and PA1010, and blends thereof with polyolefins.

Particularly important is the protection of the oxidation-sensitive silicon contained in the active solar cells.

### SUMMARY OF THE INVENTION

Accordingly an object of the present invention is to provide a film suitable for a back cover for a photovoltaic module which protects the solar cell from air oxidation.

Another object of the present invention is to provide a photovoltaic module in which the oxidative attack on the active solar cells is minimized.

These and other object have been achieved by the present invention the first embodiment of which includes a multilayer film, which comprises, in the order listed:
a) a layer of a moulding composition which comprises at least 70% by weight, based on the overall layer moulding composition, of an ethylene-vinyl alcohol (EVOH) copolymer;
b) an adhesion promoter layer;
c) a layer of a moulding composition which comprises a thermoplastic polymer;
d) optionally, an adhesion promoter layer; and
e) a layer comprising at least 35% by weight, based on the overall moulding composition, of polyamide.

In one preferred variant of the first embodiment, when the layer c) comprises a thermoplastic polymer selected from the group consisting of a polyamide, a polyester and a polyolefin, the adhesion promoter layer b) comprises at least 35% by weight of a polyolefin having 0.1 to 5% by weight of acid anhydride groups, or when the layer c) comprises a thermoplastic polymer selected from the group consisting of a polyamide and a polyester, the adhesion promoter layer b) comprises a polyamine-polyamide graft copolymer.

In another embodiment the present invention provides a photovoltaic module, comprising;
a solar cell embedded in a sealing layer; and
the multilayer film according to the first embodiment as a back cover;
wherein the layer a) of the laminate film is bonded to the sealing layer.

### DETAILED DESCRIPTION OF THE INVENTION

In the first embodiment the present invention provides a multilayer film, which comprises, in the order listed:
a) a layer of a moulding composition which comprises at least 70% by weight, based on the overall layer moulding composition, of an ethylene-vinyl alcohol (EVOH) copolymer;
b) an adhesion promoter layer;
c) a layer of a moulding composition which comprises a thermoplastic polymer;
d) optionally, an adhesion promoter layer; and
e) a layer comprising at least 35% by weight, based on the overall moulding composition, of polyamide.

In one preferred variant of the first embodiment, when the layer c) comprises a thermoplastic polymer selected from the group consisting of a polyamide, a polyester and a polyolefin, the adhesion promoter layer b) comprises at least 35% by weight of a polyolefin having 0.1 to 5% by weight of acid anhydride groups, or

when the layer c) comprises a thermoplastic polymer selected from the group consisting of a polyamide and a polyester, the adhesion promoter layer b) comprises a polyamine-polyamide graft copolymer.

In another embodiment the present invention provides a photovoltaic module, comprising;
a solar cell embedded in a sealing layer; and
the multilayer film according to the first embodiment as a back cover;
wherein the layer a) of the laminate film is bonded to the sealing layer.

In the layer a) the ethylene-vinyl alcohol copolymer (EVOH) content is preferably at least 80% and more preferably at least 90% by weight of the layer a) composition. In the layer e) the polyamide content is preferably at least 40% by weight, more preferably at least 45% by weight, especially preferably at least 50% by weight and most preferably at least 55% by weight, based on the overall e) moulding composition.

The moulding composition of the layer c) may comprise as its thermoplastic, a polyamide, a polyolefin and/or a polyester, for example. In addition there may be customary auxiliaries and additives present, more particularly light stabilizers and/or heat stabilizers, light-reflecting fillers such as titanium dioxide, for example, and also reinforcing fillers such as glass fibres, wollastonite or mica, for example.

The moulding composition of the layer e) may comprise either one of the below-specified polyamides or a plurality thereof as a mixture. In addition, up to 40% by weight, based on the overall polymer content of the moulding composition, of other thermoplastics may be present, examples being impact-modifying rubbers. Any rubbers present preferably comprise, as known to one of skill in the art, functional groups whereby compatibility with the polyamide matrix is obtained. Furthermore, the auxiliaries and additives customary for polyamides may be present, more particularly light stabilizers and/or heat stabilizers. With regard to fillers, the same applies as for the moulding composition of the layer c). In addition, the moulding composition of the layer e) may be coloured and/or may comprise a matting agent.

The composition of the adhesion promoter of the layer b) may be determined by the composition of the layer c). Where layer c) contains a moulding composition based on polyamide, polyester and/or polyolefin, then the adhesion promoter may be a moulding composition which contains at least 35%, preferably at least 40%, more preferably at least 45%, more particularly preferably at least 50% and very preferably at least 55% by weight of a polyolefin which carries 0.1 to 5%, preferably 0.3 to 4% and more preferably 0.5 to 4% by weight of acid anhydride groups. Other suitable adhesion promoters, especially in those cases where the layer c) is constructed on the basis of polyamide or polyester, comprise a polyamine-polyamide graft copolymer, optionally in combination with a polyamide which is compatible with EVOH, such as PA6, or the combination of second polyamides. Suitable compositions are disclosed for example in EP 1 065 048 A2 and also in EP 1 216 826 A1. The moulding composition of the layer b) may further comprise light stabilizers and/or heat stabilizers and also a light-reflecting filler such as titanium dioxide, for example (WO 2011066595).

The adhesion promoter of the layer d) may have any suitable composition. Suitable by way of example are the same systems as those specified above for the adhesion promoter of the layer b).

EVOH is a copolymer of ethylene and vinyl alcohol and is sometimes also referred to as EVAL. The ethylene content of the copolymer may be 25 to 60 mol % and more particularly 28 to 45 mol %. A multiplicity of types are available commercially. Reference may be made, for example, to the company brochure “Introduction to Kuraray EVAL™ Resins”, Version 1.2/9810 from the company Kuraray EVAL Europe.

The polyamide may be a partly crystalline polyamide, for example PA6, PA66, PA610, PA612, PA10, PA810, PA106, PA1010, PA11, PA1011, PA1012, PA1210, PA1212, PA814, PA1014, PA618, PA512, PA613, PA813, PA914, PA1015, PA11, PA12, or a semiaromatic polyamide, called a polyphthalamide (PPA). (The naming of the polyamides corresponds to the international standard, the first number(s) giving the number of carbon atoms of the starting diamine and the last number(s) the number of carbon atoms of the dicarboxylic acid. If only one number is mentioned, this means that the starting material was an α,ω-aminocarboxylic acid or the lactam derived therefrom; for the rest, reference is made to H. Domininghaus, Die Kunststoffe and ihre Eigenschaften [The polymers and their properties], pages 272 ff., VDI-Verlag, 1976.) Suitable PPAs are, for example, PA66/6T, PA6/6T, PA6T/MPMDT (MPMD stands for 2-methylpentamethylenediamine), PA9T, PA10T, PA11T, PA12T, PA14T and copolycondensates of these latter types with an aliphatic diamine and an aliphatic dicarboxylic acid or with an ω-aminocarboxylic acid or a lactam. Partly crystalline polyamides have an enthalpy of fusion of more than 25 J/g, measured by the DSC method to ISO 11357 in the 2nd heating step and integration of the melt peak.

The polyamide may also be a semicrystalline polyamide. Semicrystalline polyamides have an enthalpy of fusion of 4 to 25 J/g, measured by the DSC method to ISO 11357 in the 2nd heating step and integration of the melt peak. Examples of suitable semicrystalline polyamides include:
The polyamide of 1,10-decanedioic acid or 1,12-dodecanedioic acid and 4,4′-diaminodicyclohexylmethane (PA PACM10 and PA PACM12), proceeding from a 4,4′-diaminodicyclohexylmethane with a trans,trans isomer content of 35 to 65%;
copolymers based on the abovementioned partly crystalline polyamides; and
blends of the abovementioned partly crystalline polyamides and a compatible amorphous polyamide.

The polyamide may also be an amorphous polyamide. Amorphous polyamides have an enthalpy of fusion of less than 4 J/g, measured by the DSC method to ISO 11357 in the 2nd heating step and integration of the melt peak. Examples of amorphous polyamides are:
the polyamide of terephthalic acid and/or isophthalic acid and the isomer mixture of 2,2,4- and 2,4,4-trimethylhexamethylenediamine,
the polyamide of isophthalic acid and 1,6-hexamethylenediamine,
the copolyamide of a mixture of terephthalic acid/isophthalic acid and 1,6-hexamethylenediamine, optionally in a mixture with 4,4′-diaminodicyclohexylmethane,
the copolyamide of terephthalic acid and/or isophthalic acid, 3,3′-dimethyl-4,4′-diaminodicyclohexylmethane and laurolactam or caprolactam,
the (co)polyamide of 1,12-dodecanedioic acid or sebacic acid, 3,3′-dimethyl-4,4′-diaminodicyclohexylmethane, and optionally lauro-lactam or caprolactam,
the copolyamide of isophthalic acid, 4,4′-diaminodicyclohexylmethane and laurolactam or caprolactam,
the polyamide of 1,12-dodecanedioic acid and 4,4′-diaminodicyclohexylmethane (in the case of a low trans,trans isomer content),
the (co)polyamide of terephthalic acid and/or isophthalic acid and an alkyl-substituted bis(4-aminocyclohexyl)methane homologue, optionally in a mixture with hexamethylenediamine,
the copolyamide of bis(4-amino-3-methyl-5-ethylcyclohexyl)methane, optionally together with a further diamine, and isophthalic acid, optionally together with a further dicarboxylic acid,
the copolyamide of a mixture of m-xylylenediamine and a further diamine, e.g. hexamethylenediamine, and isophthalic acid, optionally together with a further dicarboxylic acid, for example terephthalic acid and/or 2,6-naphthalenedicarboxylic acid, the copolyamide of a mixture of bis(4-aminocyclohexyl)methane and bis(4-amino-3-methylcyclohexyl)methane, and aliphatic dicarboxylic acids having 8 to 14 carbon atoms, and
polyamides or copolyamides of a mixture comprising 1,14-tetradecanedioic acid and an aromatic, arylaliphatic or cycloaliphatic diamine.

These examples may be varied to a very substantial degree by addition of further components (for example caprolactam, laurolactam or diamine/dicarboxylic acid combinations) or by partial or full replacement of starting components by other components.

Polyetheresteramides are described in DE-A-25 23 991 and DE-A-27 12 987; they contain a polyether diol as a comonomer. Polyetheramides are described in DE-A-30 06 961; they contain a polyether diamine as a comonomer.

In the polyether diol or the polyether diamine, the polyether unit may be based, for example, on 1,2-ethanediol, 1,2-propanediol, 1,3-propanediol, 1,4-butanediol or 1,3-butanediol. The polyether unit may also be of mixed structure, for instance with random or blockwise distribution of the units originating from the diols. The weight-average molar mass of the polyether diols or polyether diamines may be 200 to 5000 g/mol and preferably 400 to 3000 g/mol; the proportion thereof in the polyetheresteramide or polyetheramide may preferably be 4 to 60% by weight and more preferably 10 to 50% by weight. Suitable polyether diamines may be obtained by conversion of the corresponding polyether diols by reductive amination or coupling to acrylonitrile with subsequent hydrogenation; they are commercially available, for example, in the form of the JEFFAMINE® D or ED products or of the ELASTAMINE® products from Huntsman Corp., or in the form of the Polyetheramine D series from BASF SE. It is also possible to additionally use smaller amounts of a polyether triamine, for example a JEFFAMINE® T product, if a branched polyetheramide is to be used. Preference is given to using polyether diamines or polyether triamines which contain an average of at least 2.3 carbon atoms in the chain per ether oxygen atom. According to the invention, polyetheramides are preferred due to better hydrolysis resistance.

Useful thermoplastic polyesters include linear thermoplastic polyesters. These may be prepared by polycondensation of diols with dicarboxylic acid or polyester-forming derivatives thereof such as dimethyl esters. Suitable diols have the formula HO—R—OH where R is a divalent branched or unbranched aliphatic and/or cycloaliphatic radical having 2 to 40 and preferably 2 to 12 carbon atoms. Suitable dicarboxylic acids have the formula HOOC—R′—COOH where R′ is a divalent aromatic radical having 6 to 20 and preferably 6 to 12 carbon atoms.

Examples of diols include ethylene glycol, trimethylene glycol, tetramethylene glycol, hexamethylene glycol, neopentyl glycol, cyclohexanedimethanol, and the C36 diol dimer diol. The diols may be used alone or as a diol mixture. Up to 25 mol % of the diol may optionally be replaced by a polyalkylene glycol of the formula:

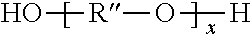

where R″ is a divalent radical having 2 to 4 carbon atoms and x may assume a value from 2 to 50.

Examples of useful aromatic dicarboxylic acids include terephthalic acid, isophthalic acid, 1,4-, 1,5-, 2,6- or 2,7-naphthalenedicarboxylic acid, diphenic acid and diphenyl ether 4,4′-dicarboxylic acid. Up to 30 mol % of these dicarboxylic acids may be replaced by aliphatic or cycloaliphatic dicarboxylic acids, for example succinic acid, adipic acid, sebacic acid, dodecanedioic acid or cyclohexane-1,4-dicarboxylic acid.

Examples of suitable polyesters include polyethylene terephthalate, polypropylene terephthalate, polybutylene terephthalate, polyethylene 2,6-naphthalate, polypropylene 2,6-naphthalate and polybutylene 2,6-naphthalate.

Methods to prepare these polyesters are described DE-A 24 07 155, 24 07 156; and in Ullmanns Encyclopädie der technischen Chemie, 4th ed., Vol. 19, pages 65 ff., Verlag Chemie, Weinheim, 1980).

The polyolefin may be, for example, a polyethylene or preferably a polypropylene. The polypropylene may in principle be of any customary commercial polypropylene type, examples being isotactic or syndiotactic homopolypropylene, a random copolymer of propene with ethene and/or but-1-ene, a propene-ethene block copolymer and the like. The polypropylene may be prepared by any known process, as for example by the Ziegler-Natta method or by means of metallocene catalysis. It is possible for there to be an impact-modifying component present, such as EPM rubber or EPDM rubber or SEBS, for example.

The polyamine-polyamide graft copolymers are described in EP 1 065 048 A2.

In preferred embodiments, the individual film layers may have the following thicknesses:
layer according to a): 50 to 250 μm and preferably 100 to 200 μm;
layer according to b): 15 to 100 μm and preferably 25 to 50 μm;
layer according to c): 100 to 500 μm and preferably 150 to 400 μm;
layer according to d): 3 to 40 μm and preferably 5 to 25 μm;
layer according to e): 15 to 100 μm and preferably 25 to 50 μm.

The multilayer film used in accordance with the invention may be optimized for the fewest possible number of layers in conjunction with generally effective adhesion. It may be produced by conventionally known methods, for example coextrusion or lamination. It is bonded to the sealing layer into which the solar cell is embedded, for example, by lamination or adhesive bonding. Due to the EVOH content in the layer according to a), good adhesion to the sealing layer may be obtained in the case of lamination. The sealing layer used may be any material commonly used for such utility.

The present invention also provides a photovoltaic module which has been produced using a multilayer film according to embodiments of the present invention.

Having generally described this invention, a further understanding can be obtained by reference to certain specific examples which are provided herein for purposes of illustration only, and are not intended to be limiting unless otherwise specified.

### EXAMPLES

For this purpose, the moulding compositions which follow were produced; “parts” are always parts by weight.

Compound for Layer A (O₂ Barrier):

95 parts of EVAL™ F101 B from Kuraray and 5 parts of the titanium dioxide Sachtleben R 420 were mixed with the aid of a twin-screw extruder (Coperion Werner & Pfleiderer ZSK 25 WLE, 36 L/D) at a barrel temperature of 220° C. The extrudate was cooled with the aid of a water bath and chopped; the pellets were subsequently dried in a forced-air oven at 80° C. for 12 hours.

Compound for Layer B (Adhesion Promoter):

59.3 parts of PA612, 18 parts of PA6, 2 parts of polyamine-polyamide graft copolymer (prepared according to EP 1 065 236 A2 from 87.063% by weight of laurolactam, 0.164% by weight of dodecanedioic acid, 8.205% by weight of 50% Lupasol® G 100, 0.010% by weight of 50% hypophosphorous acid and 4.558% by weight of demineralized water), 0.5 part of IRGANOX® 1098 (a sterically hindered phenolic antioxidant), 0.2 part of TINUVIN® 312 (UV absorber) and 20 parts of the titanium dioxide Sachtleben R 420 were mixed with the aid of a twin-screw extruder (Coperion Werner & Pfleiderer ZSK 25 WLE, 36 L/D) at a barrel temperature of 240° C. The extrudate was cooled with the aid of a water bath and chopped; the pellets were subsequently dried in a forced-air oven at 80° C. for 12 hours.

Compound for Layer C (Middle Layer):

75.6 parts of Hostalen® EPD60R (propylene-ethylene block copolymer), 4 parts of LOTADER® AX 8900 (terpolymer of ethylene, methyl acrylate and glycidyl methacrylate), 20 parts of TEC 110 kaolin and 0.4 part of IRGANOX® 1010 (sterically hindered phenolic antioxidant) were mixed with the aid of a twin-screw extruder (Coperion Werner & Pfleiderer ZSK 25 WLE, 36 L/D) at a barrel temperature of 200° C. The extrudate was cooled with the aid of a water bath and chopped; the pellets were subsequently dried in a forced-air oven at 80° C. for 12 hours.

Compound for Layer D (Adhesion Promoter):

55.6 parts of Hostalen® EPD60R, 40 parts of VESTAMID® L1901 (PA12), 4 parts of LOTADER® AX 8900 and 0.4 part of IRGANOX® 1010 were mixed with the aid of a twin-screw extruder (Coperion Werner & Pfleiderer ZSK 25 WLE, 36 L/D) at a barrel temperature of 200° C. The extrudate was cooled with the aid of a water bath and chopped; the pellets were subsequently dried in a forced-air oven at 80° C. for 12 hours.

Compound for Layer E (Outside, Backside of Module):

79.3 parts of VESTAMID® L1901 nf, 0.5 part of IRGANOX® 1098, 0.2 part of TINUVIN® 312 and 20 parts of the titanium dioxide Sachtleben R 420 were mixed with the aid of a twin-screw extruder (Coperion Werner & Pfleiderer ZSK 25 WLE, 36 L/D) at a barrel temperature of 220° C. The extrudate was cooled with the aid of a water bath and chopped; the pellets were subsequently dried in a forced-air oven at 80° C. for 12 hours.

Extrusion of Multilayer Films:

A multilayer film system from Collin (co-extrusion feed block for 5-layer films) was used to produce a four-layer and a five-layer film (processing temperature approx. 230° C.). The layer thickness distribution was set as follows:
A/B/C/D/E: 100 μm/50 μm/150 μm/20 μm/50 μm
B/C/D/E: 50 μm/150 μm/20 μm/50 μm (comparison without layer A)

The results are shown in Table 1.

TABLE 1
Examples; O₂ permeation to ISO 15105-2 at 23° C.
and 50% r.h. in cm³/(m²•d•bar)

| | Layer distribution | O₂ permeation |
|---|---|---|
| Example | A/B/C/D/E | 0.4 |
| Comparative Example 1 | B/C/D/E | 74 |

Numerous modifications and variations on the present invention are possible in light of the above description. It is therefore to be understood that within the scope of the appended claims, the invention may be practiced otherwise than as specifically described herein.

1. A multilayer film, comprising, in the order listed:
a) a layer of a moulding composition which comprises at least 70% by weight, based on the overall layer moulding composition, of an ethylene-vinyl alcohol (EVOH) copolymer;
b) an adhesion promoter layer;
c) a layer of a moulding composition which comprises a thermoplastic polymer;
d) optionally, an adhesion promoter layer; and
e) a layer comprising at least 35% by weight, based on the overall moulding composition, of polyamide.

2. The multilayer film according to claim 1, wherein
when the layer c) comprises a thermoplastic polymer selected from the group consisting of a polyamide, a polyester and a polyolefin, the adhesion promoter layer b) comprises at least 35% by weight of a polyolefin having 0.1 to 5% by weight of acid anhydride groups, or
when the layer c) comprises a thermoplastic polymer selected from the group consisting of a polyamide and a polyester, the adhesion promoter layer b) comprises a polyamine-polyamide graft copolymer

3. The multilayer film according to claim 1, wherein
a thickness of the layer a) is from 50 to 250 μm.

4. The multilayer film according to claim 3, wherein
a thickness of the layer b) is from 15 to 100 μm,
a thickness of the layer c) is from 100 to 500 μm, and
a thickness of the layer e) is from 15 to 100 μm.

5. The multilayer film according to claim 4, which comprises a layer d) and a thickness of the layer d) is from 3 to 100 μm.

6. The multilayer film according to claim 1, wherein
an ethylene content of the EVOH is from 25 to 60 mol %.

7. The multilayer film according to claim 1, wherein at least the polyamide of layer e) comprises at least one selected from the group consisting of a partly crystalline polyamide having an enthalpy of fusion of more than 25 J/g, a semicrystalline polyamide having an enthalpy of fusion of from 4 to 25 J/g and an amorphous polyamide having an enthalpy of fusion of less than 4 J/g.

8. The multilayer film according to claim 1, wherein the polyolefin is selected from the group consisting of polyethylene, anisotactic or atactic homopolypropylene, a random copolymer of propene with ethene, a random copolymer of propene, ethene and 1-butene, and an ethylene-propylene block copolymer any of which optionally comprising an impact-modifying component.

9. The multilayer film according to claim 1 wherein at least one of the layer a), the layer b) and the layer c) further comprises titanium dioxide.

10. A photovoltaic module, comprising;
a solar cell embedded in a sealing layer; and
the multilayer film according to claim 1 as a back cover;
wherein the layer a) of the laminate film is bonded to the sealing layer.

11. The photovoltaic module according to claim 10,
wherein a thickness of the layer a) is from 50 to 250 μm.

12. The photovoltaic module according to claim 11, wherein
a thickness of the layer b) is from 15 to 100 μm,
a thickness of the layer c) is from 100 to 500 μm, and
a thickness of the layer e) is from 15 to 100 μm.

13. The photovoltaic module according to claim 12,
which comprises a layer d) and a thickness of the layer d) is from 3 to 100 μm.

14. The photovoltaic module according to claim 12, wherein an ethylene content of the EVOH is from 25 to 60 mol %.

15. The photovoltaic module according to claim 10, wherein
the layer a) comprises ethylene vinyl alcohol and titanium dioxide,
the layer b) comprises a polyamine-polyamide graft copolymer and a EVOH compatible polyamide,
the layer c) comprises a polyolefin,
the layer d) is present and comprises a polyamide and polyolefin, and
the layer e) further comprises titanium dioxide.
